(19) United States
(12) Patent Application Publication
(10) Pub. No.: US 2014/0118939 A1
(43) Pub. Date: May 1, 2014

(54) HEAT DISSIPATION MODULE, ELECTRONIC DEVICE AND ITS DUST REMOVAL METHOD

(71) Applicants: INVENTEC(PUDONG) TECHNOLOGY CORPORATION, Shanghai (CN); INVENTEC CORPORATION, Taipei (TW)

(72) Inventors: Wei-Yi Lin, Taipei (TW); Hsin-Yi Wang, Taipei (TW); Yi-Lun Cheng, Taipei (TW)

(73) Assignees: INVENTEC CORPORATION, Taipei (TW); INVENTEC (PUDONG) TECHNOLOGY CORPORATION, Shanghai (CN)

(21) Appl. No.: 13/787,034

(22) Filed: Mar. 6, 2013

(30) Foreign Application Priority Data
Oct. 31, 2012 (CN) 201210427828.6

(51) Int. Cl. H05K 7/20

(52) U.S. Cl. CPC H05K 7/20181
USPC 361/695

(57) ABSTRACT

A dust removal method of an electronic device is provided that the electronic device includes a first body, a heat dissipation module and a cover plate. The first body includes a heat dissipation opening. The heat dissipation module comprises a fan and a fin assembly. The fan has a fan case body and a blade assembly. The fan case body includes an air inlet, an air outlet and a dust collecting opening. The air outlet and the heat dissipation opening are connected with each other. The cover plate is installed in the fan case body and adjacent to the dust collecting opening. The blade assembly turns and the cover plate covers the dust collecting opening. An air current flows in from the air inlet and flows out from the air outlet.

### CROSS-REFERENCE TO RELATED APPLICATIONS

This non-provisional application claims priority under 35 U.S.C. §119(a) on Patent Application No(s). 201210427828.6 filed in China, P.R.C. on Oct. 31, 2012, the entire contents of which are hereby incorporated by reference.

### BACKGROUND OF THE INVENTION

1. Technical Field of the Invention

The present disclosure relates to a heat dissipation module, an electronic device and its dust removal method, and more particularly to a heat dissipation module, an electronic device and its dust removal method for cleaning heat dissipation fins.

2. Description of the Related Art

As the technology in electronic field keeps evolving, the efficiency of electronic components keeps enhancing, too. However, the enhancement on the efficiency of electronic components causes the amount of heat produced to increase. The heat keeps accumulating in the electronic components, causing the temperatures of the electronic components to increase. The electronic components will easily crash or even burn up if the heat cannot be removed effectively from the electronic components in order to lower the temperatures. Therefore, the problem that the electronic industry faces is how to remove the heat effectively instead of working on optimizing the efficiency.

Generally speaking, the electronic industry employs an air-cooled heat dissipation device to remove the heat produced. The air-cooled heat dissipation device comprises a fan, a heat dissipation fin and a heat pipe. The heat dissipation fin is disposed at an air outlet of the fan as well as the heat pipe is connected to a heat source and the heat dissipation fin in order to conduct the heat of heat source to the heat dissipation fin. The fan operates and turns to form an air current to flow through the heat dissipation fin, and the air current exchanges heat with the heat dissipation fin in order to remove the heat in the heat dissipation fin. However, when the air current formed by the operation of the air-cooled heat dissipation device is blown toward the heat dissipation fin, not only the heat of the heat dissipation fin can be removed but also dust in the air is blown toward the heat dissipation fin. Therefore, after a certain period of operating the air-cooled heat dissipation device, dust will cover on the heat dissipation fin to block the flowing of the heat dissipating air current, and the heat dissipation efficiency of the air-cooled heat dissipation device will be affected. Therefore, a way of how to clean out the dust covered on the heat dissipation fin effectively is a problem for designers to solve.

### SUMMARY OF THE INVENTION

An embodiment of the disclosure provides a dust removal method of an electronic device. The electronic device comprises a first body, a heat dissipation module, a first cover plate and a second cover plate. The first body includes a heat dissipation opening. The heat dissipation module is assembled in the first body. The heat dissipation module comprises a fan and a fin assembly. The fan comprises a fan case body and a blade assembly disposed inside the fan case body. The fan case body includes an air inlet, an air outlet and a dust collecting opening. The air outlet and the heat dissipation opening are connected with each other. The first cover plate is installed in a position of the first body adjacent to the dust collecting opening or is installed in a position of the fan case body adjacent to the dust collecting opening. The first cover plate is used for sealing off the dust collecting opening. The second cover plate is installed in the first body and is used for sealing off the air inlet. When the blade assembly turns toward a first turning direction, the first cover plate covers the dust collecting opening, a heat dissipating air current flows inside the heat dissipation module from the air inlet and flows out from the air outlet towards the fin assembly. In the dust removal method, the second cover plate is inserted for sealing off the air inlet of the fan case body. The first cover plate is turned pivotally toward the blade assembly in order to expose the dust collecting opening. The blade assembly is turned toward the first turning direction, and a dust collecting air current is suitable for flowing outside the dust collecting opening from the air outlet along the first turning direction.

Another embodiment of the disclosure provides an electronic device for performing a heat dissipation operation or a dust collecting operation. The electronic device comprises a first body, a heat dissipation module, a first cover plate and a second cover plate. The first body includes a heat dissipation opening. The heat dissipation module is assembled in the first body. The heat dissipation module comprises a fan which includes a fan case body and a blade assembly disposed inside the fan case body. The fan case body includes an air inlet, an air outlet and a dust collecting opening. The air outlet and the heat dissipation opening are connected with each other. The first cover plate is installed in a position of the first body adjacent to the dust collecting opening or is installed in a position of the fan case body adjacent to the dust collecting opening. The first cover plate is used for sealing off the dust collecting opening. The second cover plate is installed in the first body and is used for sealing off the air inlet. During the heat dissipation operation, the blade assembly turns toward a first turning direction, the first cover plate covers the dust collecting opening, a heat dissipating air current flows inside the heat dissipation module from the air inlet and flows out from the air outlet, during the dust collecting operation, the blade assembly turns toward the first turning direction, the first cover plate opens the dust collecting opening, the second cover plate seals off the air inlet, and a dust collecting air current flows outside the dust collecting opening from the air outlet along the first turning direction.

Still another embodiment of the disclosure provides a heat dissipation module for assembling in a first body to be adapted to perform a heat dissipation operation or for installing with a second cover plate to be adapted to perform a dust collecting operation. The heat dissipation module comprises a fan and a first cover plate. The fan comprises a fan case body and a blade assembly. The blade assembly is disposed inside the fan case body. The fan case body includes an air inlet, an air outlet and a dust collecting opening. The air outlet and the heat dissipation opening are connected with each other. The first cover plate is installed in a position of the first body adjacent to the dust collecting opening or in a position of the fan case body adjacent to the dust collecting opening. The first cover plate is used for sealing off the dust collecting opening. During the heat dissipation operation, the blade assembly turns toward a first turning direction, the first cover plate covers the dust collecting opening, and a heat dissipating air current flows inside the heat dissipation module from the air inlet and flows out from the air outlet. During the dust collecting operation, the blade assembly turns toward the first turning direction, the first cover plate opens the dust collecting opening, the second cover plate seals off the air inlet, and a dust collecting air current flows outside the dust collecting opening from the air outlet along the first turning direction.

### BRIEF DESCRIPTION OF THE DRAWINGS

The disclosure will become more fully understood from the detailed description given herein below for illustration only, and thus does not limit the disclosure, and wherein:

FIG. 1A is a side view of an electronic device according to an embodiment of the disclosure;

FIG. 1B is a top view of an electronic device according to an embodiment of the disclosure;

FIG. 1C is another side view of an electronic device according to an embodiment of the disclosure;

FIG. 2 is a perspective view of a fan in FIG. 1;

FIG. 3A is a top view of a heat dissipation module in FIG. 1 under a heat dissipation operation;

FIGS. 3B and 3C are top views of the heat dissipation module in FIG. 1 under a dust collecting operation;

FIG. 4 is a perspective view of the fan being installed with a second cover plate according to a second embodiment of the disclosure;

FIG. 5A is a top view of the heat dissipation module in FIG. 4 under the heat dissipation operation;

FIGS. 5B and 5C are top views of the heat dissipation module in FIG. 4 under the dust collecting operation;

FIG. 6A is a side view of the electronic device under the heat dissipation operation according to a third embodiment of the disclosure; and

FIG. 6B is a side view of the electronic device under the dust collecting operation according to the third embodiment of the disclosure.

### DETAILED DESCRIPTION

In the following detailed description, for purposes of explanation, numerous specific details are set forth in order to provide a thorough understanding of the disclosed embodiments. It will be apparent, however, that one or more embodiments may be practiced without these specific details. In other instances, well-known structures and devices are schematically shown in order to simplify the drawing.

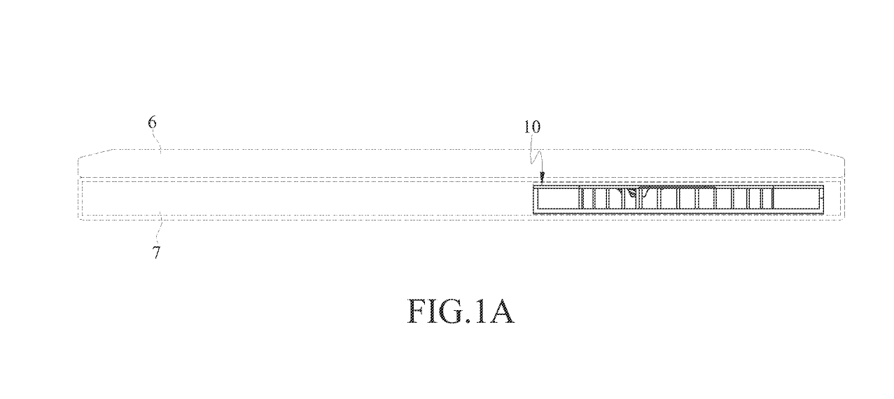

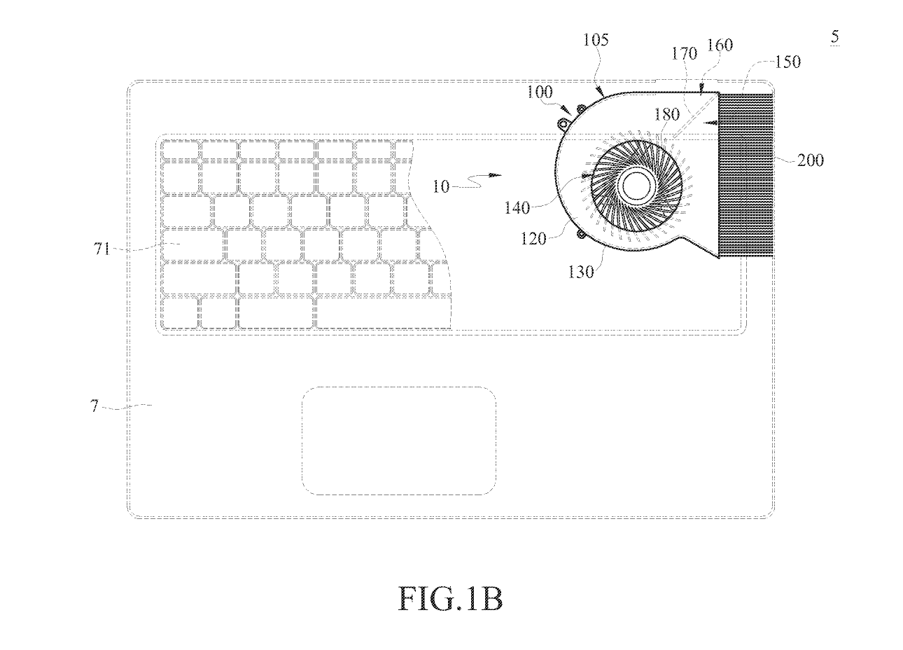

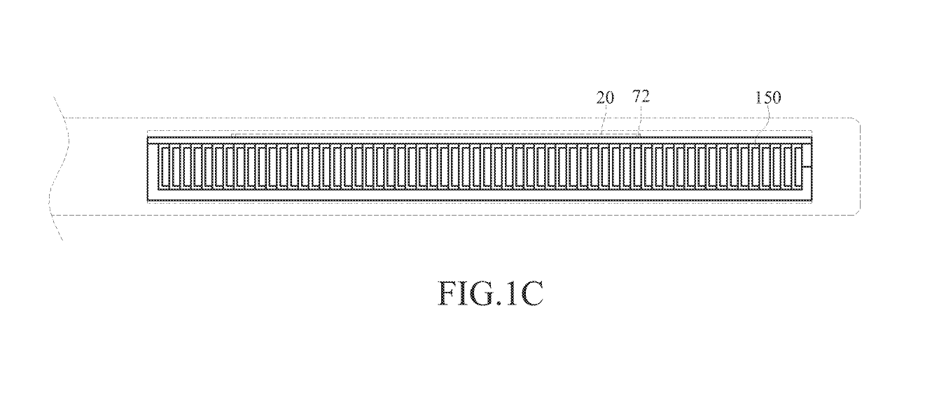

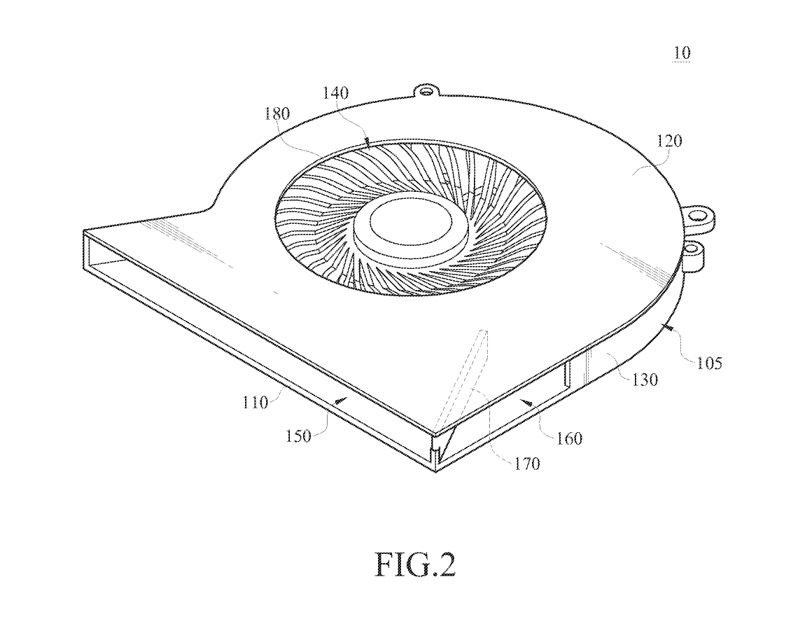

Please refer to FIGS. 1A to 2. FIG. 1A is a side view of an electronic device according to an embodiment of the disclosure. FIG. 1B is a top view of an electronic device according to an embodiment of the disclosure. FIG. 1C is another side view of an electronic device according to an embodiment of the disclosure. FIG. 2 is a perspective view of a fan in FIG. 1. An electronic device 5 of this embodiment is suitable for performing a heat dissipation operation or a dust collecting operation. Detailed descriptions are mentioned hereinafter.

The electronic device 5 of this embodiment comprises a first body 7, a heat dissipation module 10, a first cover plate 170 and a second cover plate 20. The first body 7 is disposed with a keyboard 71, and the first body 7 includes an inserting opening 72 and a heat dissipation opening 73. The keyboard 71 faces toward a second body 6. The inserting opening 72 and the heat dissipation opening 73 are disposed on the same side of the first body 7. The inserting opening 72 is used for being inserted by the second cover plate 20. The heat dissipation module 10 is assembled in the first body 7. The heat dissipation module 10 comprises a fan 100 and a fin assembly 200. The fan 100 comprises a fan case body 105 and a blade assembly 180 disposed inside the fan case body 105. The fan case body 105 includes an air inlet 140, an air outlet 150 and a dust collecting opening 160. The air outlet 150 and the heat dissipation opening 73 are connected with each other. The first cover plate 170 is installed in a position of the first body 7 adjacent the dust collecting opening 160, or in a position of the fan case body 105 adjacent the dust collecting opening 160. The first cover plate 170 is used for sealing off the dust collecting opening 160. The second cover plate 20 is disposed in the first body 7 and is used for sealing off the air inlet 140.

To describe in detail, the fan case body 105 comprises a bottom plate 110, a top plate 120 and a side plate 130. The bottom plate 110, the top plate 120 and the side plate 130 are connected with each other. The side plate 130 is disposed between the bottom plate 110 and the top plate 120. The air inlet 140 is disposed on the top plate 120. The air outlet 150 and the dust collecting opening 160 are disposed on the side plate 130, and are separated from each other by a distance. More specifically, in this embodiment, the air outlet 150 is disposed adjacent to the dust collecting opening 160 as well as the first cover plate 170 is pivotally connected to the side plate 130 between the air outlet 150 and the dust collecting opening 160. The first cover plate 170 can be turned pivotally toward the blade assembly 180, but does not limit this disclosure. In other embodiments, an end of the first cover plate 170 may be pivotally connected along an axis to the position of the first body 7 adjacent the dust collecting opening 160. In the dust collecting operation, another end of the first cover plate 170 turns around the axis in order to open the dust collecting opening 160.

In this embodiment, the blade assembly 180 is disposed between the bottom plate 110 and the top plate 120. The side plate 130 surrounds the blade assembly 180 inside the fan case body 105. The blade assembly 180 can be turned toward a first turning direction. In this embodiment, the air inlet 140 is disposed on the top plate 120, but does not limit this disclosure. In other embodiments, the air inlet 140 can be disposed on the bottom plate 110, or the air inlet 140 may be disposed on the bottom plate 110 and the top plate 120 at the same time. Moreover, the fin assembly 200 is disposed at the air outlet 150 of the fan 100.

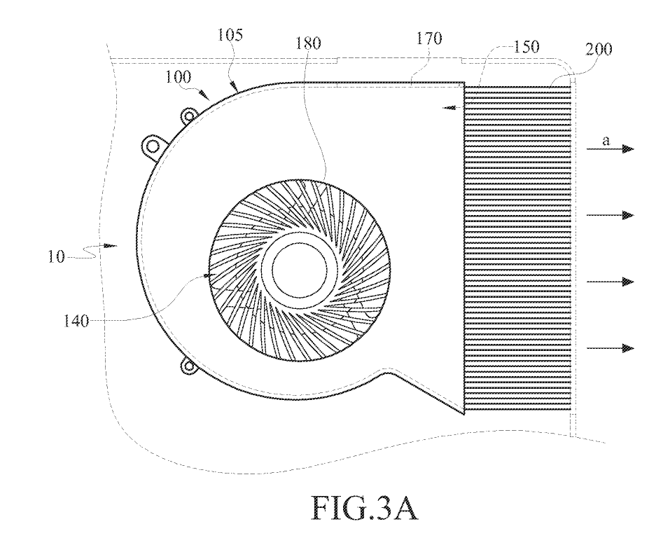

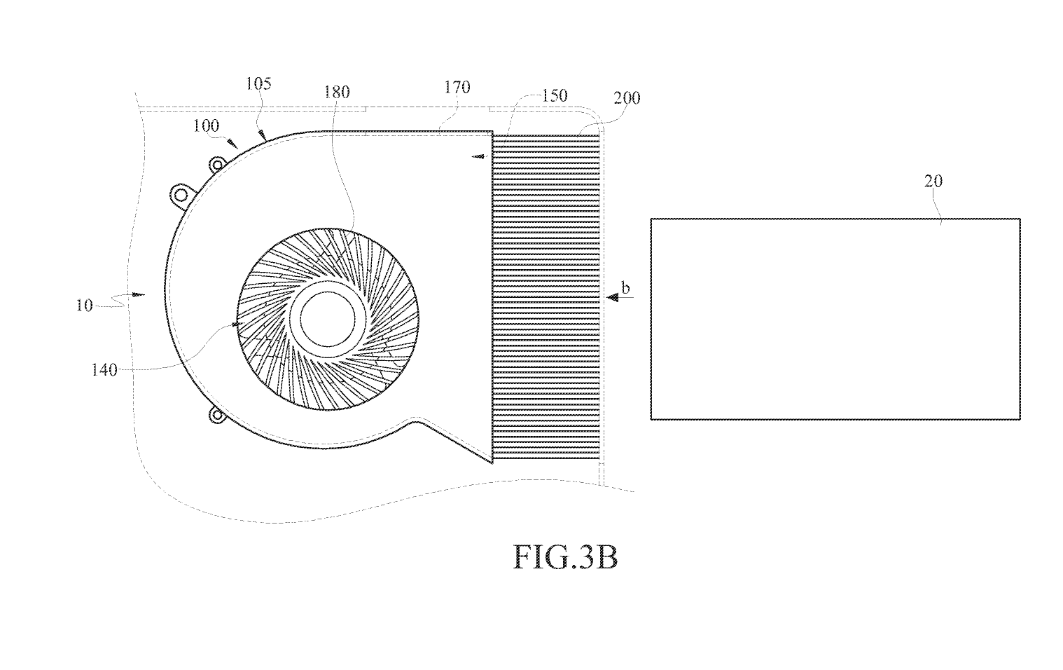

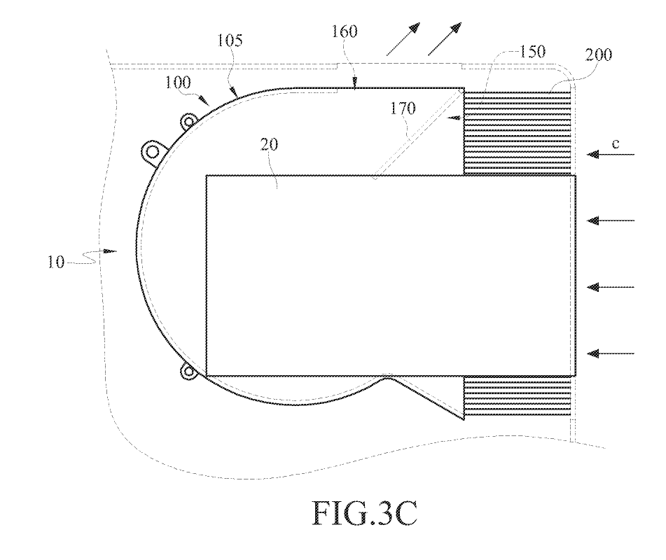

In this embodiment, the dust removal effect for the heat dissipation module 10 is achieved by applying the second cover plate 20 to cover the air inlet 140. The second cover plate 20 can be made of a plastic material. Please refer to FIGS. 3A to 3C. FIG. 3A is a top view of the heat dissipation module in FIG. 1 under the heat dissipation operation. FIGS. 3B and 3C are top views of the heat dissipation module in FIG. 1 under the dust collecting operation.

Firstly, the heat dissipation module 10 under the heat dissipation operation is described hereinafter. As shown in FIG. 3A, the dust collecting opening 160 is sealed off by the first cover plate 170, the blade assembly 180 of the heat dissipation module 10 is turned toward a turning direction to cause a heat dissipating air current ‘a’ to flow inside the heat dissipation module 10 from the air inlet 140 before to flow outside toward the fin assembly 200 from the air outlet 150. Therefore, the heat of the fin assembly 200 is removed.

Then, when the dust is gradually accumulated on the fin assembly 200 as well as affecting the heat dissipation efficiency of the heat dissipation module 10, the dust on the fin assembly 200 has to be cleaned out effectively in order to restore the heat dissipation module 10 to the original heat dissipation efficiency. The dust removal method of the heat dissipation module 10 under the dust collecting operation is described hereinafter.

Then, as shown in FIG. 3B, the second cover plate 20 is inserted (along a direction indicated by an arrow ‘b’) in order to seal off the air inlet 140 of the fan case body 105.

Then, as shown in FIG. 3C, the first cover plate 170 is pivotally turned toward the blade assembly 180 in order to expose the dust collecting opening 160. The blade assembly 180 is turned toward the first turning direction to cause a dust collecting air current to flow outside the dust collecting opening 160 from the air outlet 150 along the first turning direction. In order not to let the dust to be discharged (namely, exhausted) from the dust collecting opening 160 directly, in this embodiment and some other embodiments, a dust collecting bag (not shown in the drawings) is installed at the dust collecting opening 160 for accumulating the dust in the dust collecting bag.

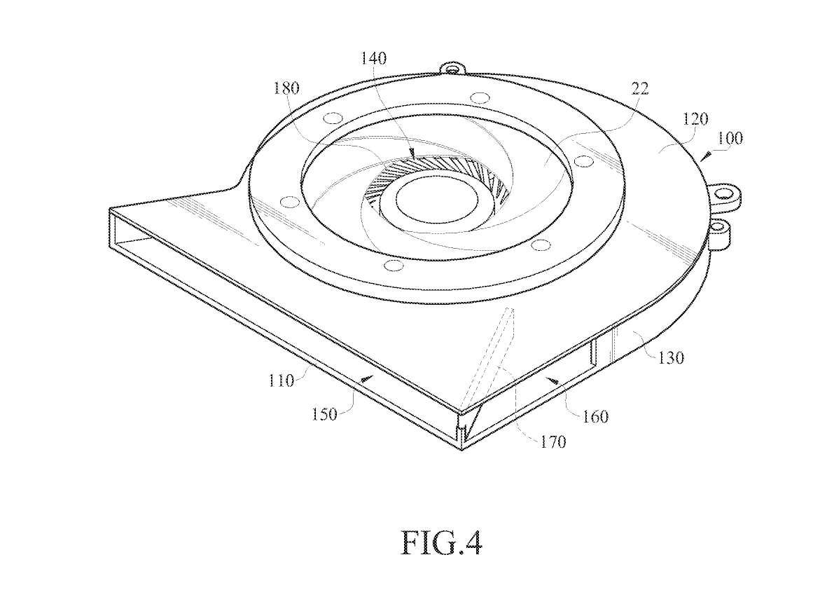

In the above embodiment, the structure of the second cover plate 20 should not be construed as a limitation to the present disclosure. In other embodiments, the second cover plate 20 can also be embodied as a plurality of air blocking plates 22. Please refer to FIG. 4, which is a perspective view of the fan being installed with the air blocking plates 22 according to a second embodiment of the disclosure. The structures of the fan 100 and the fin assembly 200 in this embodiment are the same as the embodiment in FIG. 1, and therefore will not be described again.

The fan 100 of this embodiment comprises a plurality of the air blocking plates 22. The plurality of air blocking plates 22 are separated by a distance and are pivotally connected to the top plate 120 along a circumference of the air inlet 140. The air blocking plates 22 may be turned pivotally relative to the top plate 120 in order to seal off the air inlet 140 or expose the air inlet 140. Furthermore, the way of pivotally turning the air blocking plates 22 can be achieved manually or automatically.

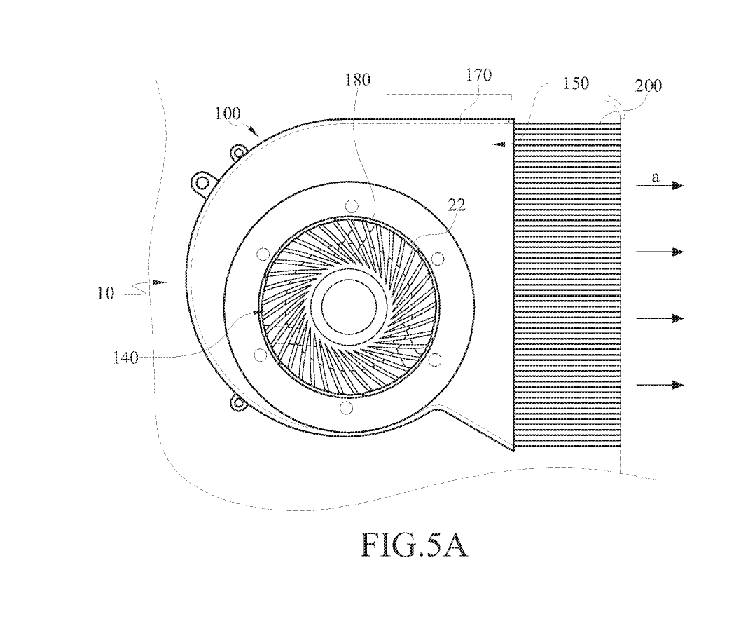

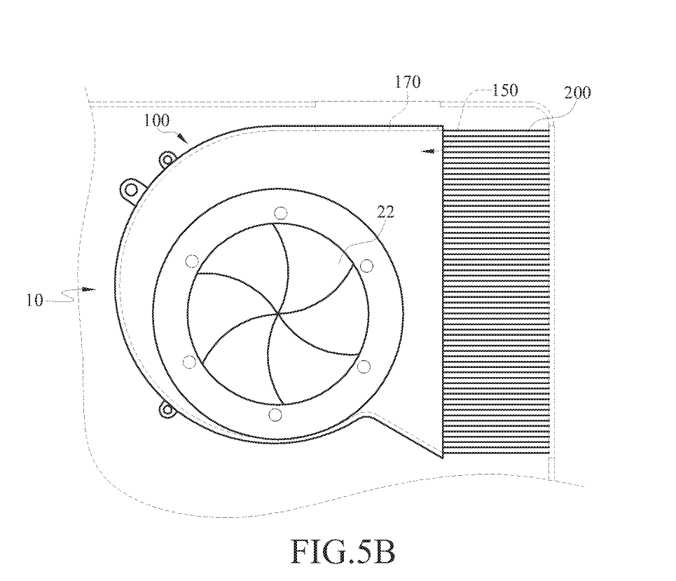

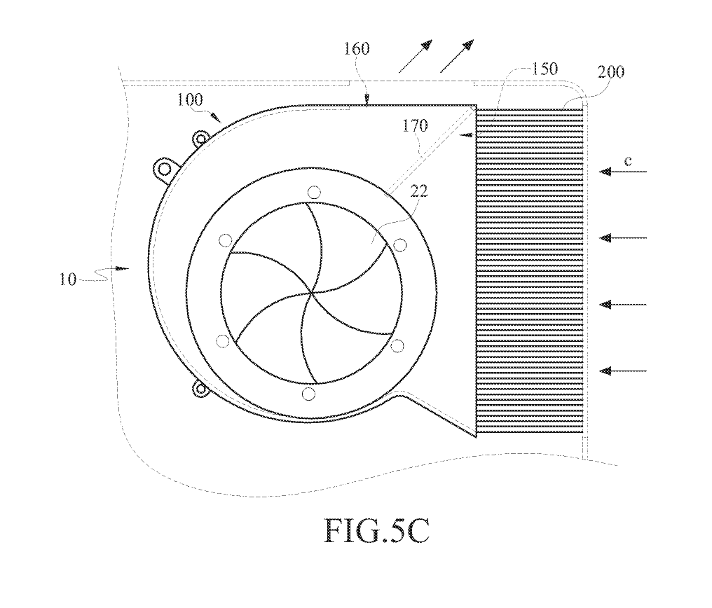

Please refer to FIGS. 5A to 5C. FIG. 5A is a top view of the heat dissipation module in FIG. 4 under the heat dissipation operation. FIGS. 5B and 5C are top views of the heat dissipation module in FIG. 4 under the dust collecting operation.

Firstly, the heat dissipation module 10 under the heat dissipation operation is described hereinafter. As shown in FIG. 5A, the dust collecting opening 160 is sealed off by the first cover plate 170, the blade assembly 180 of the heat dissipation module 10 is turned toward a turning direction to cause a heat dissipating air current a to flow inside the heat dissipation module 10 from the air inlet 140 before to flow outside toward the fin assembly 200 from the air outlet 150. Therefore, the heat of the fin assembly 200 is removed.

Then, when the dust is gradually accumulated on the fin assembly 200 and affecting the heat dissipation efficiency of the heat dissipation module 10, the dust on the fin assembly 200 has to be cleaned out effectively in order to restore the heat dissipation module 10 to the original heat dissipation efficiency. The dust removal method of the heat dissipation module 10 under the dust collecting operation is described hereinafter.

Then, as shown in FIG. 5B, the air blocking plates 22 are pivotally turned in order to seal off the air inlet 140 of the fan 100 by the air blocking plates 22.

Then, as shown in FIG. 5C, the first cover plate 170 is pivotally turned toward the blade assembly 180 in order to expose the dust collecting opening 160. The blade assembly 180 is turned toward the first turning direction to cause the dust collecting air current to flow outside the dust collecting opening 160 from the air outlet 150 along the first turning direction.

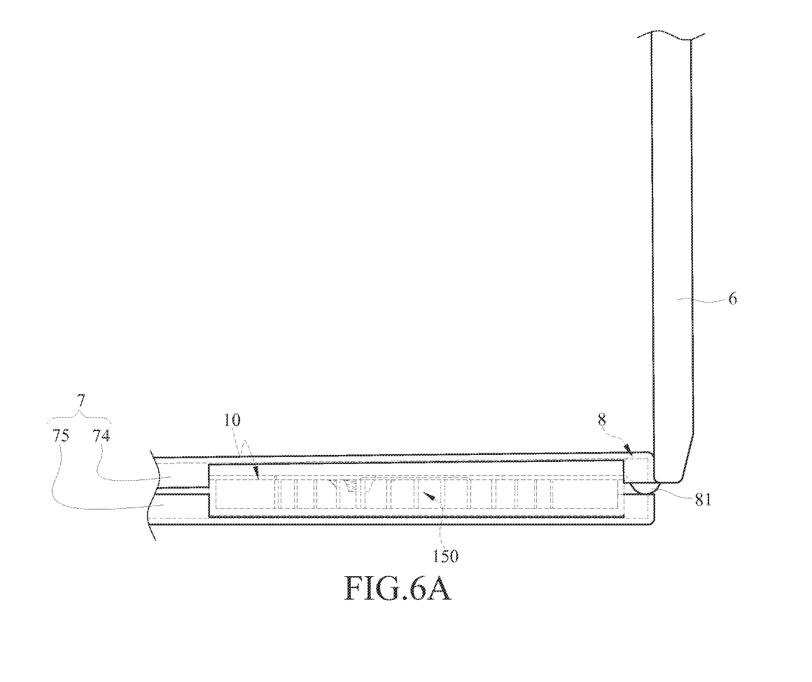

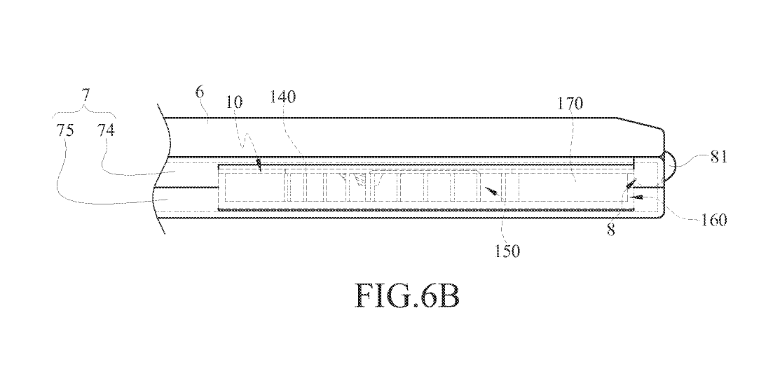

Please refer to FIGS. 1A, 1B, 1C, 6A and 6B. FIG. 6A is a side view of the electronic device under the heat dissipation operation according to a third embodiment of the disclosure. FIG. 6B is a side view of the electronic device under the dust collecting operation according to the third embodiment of the disclosure. The electronic device 5 of this embodiment further comprises the second body 6 and a pivotal turning mechanism 8. The pivotal turning mechanism 8 is pivotally connected between the first body 7 and the second body 6. The first body 7 has a first portion 74 and a second portion 75 disposed underneath the first portion 74. The first portion 74 comprises the keyboard 71. The heat dissipation module 10 is disposed in the second portion 75. The pivotal turning mechanism 8 is pivotally connected to the second body 6 and the first portion 74 of the first body 7. The pivotal turning mechanism 8 has a protruding portion 81. When an end of the second body 6 is turned toward a direction away from the first body 7, the protruding portion 81 of the pivotal turning mechanism 8 is pressed against the second portion 75 of the first body 7 to drive at least a part of the first portion 74 to detach from the second portion 75.

Firstly, the heat dissipation module 10 under the heat dissipation operation is described hereinafter. As shown in FIG. 6A, the protruding portion 81 of the pivotal turning mechanism 8 is pressed against the second portion 75 of the first body 7 to drive at least a part of the first portion 74 to detach from the second portion 75 as well as to expose the air inlet 140. At this point, a heat dissipating air current flows inside the heat dissipation module 10 from the air inlet 140 before flowing outside toward the fin assembly 200 from the air outlet 150. Therefore, the heat of the fin assembly 200 is removed.

Then, the heat dissipation module 10 under the dust collecting operation is described hereinafter. As shown in FIG. 6B, the second body 6 is drawn close to the first body 7. At this point, the first portion 74 of the first body 7 is pressed on the second portion 75 in order to seal off the air inlet 140. At this point, the first cover plate 170 is pivotally turned toward the blade assembly 180 in order to expose the dust collecting opening 160. The blade assembly 180 is turned toward the first turning direction to cause the dust collecting air current to flow outside the dust collecting opening 160 from the air outlet 150 along the first turning direction.

According to the heat dissipation module, the electronic device and its dust removal method provided by the disclosure, the air inlet is sealed off by the second cover plate as well as the first cover plate is opened to expose the dust collecting opening for exhausting air such that when the blade assembly of the fan is turned toward the first turning direction, the dust collecting air current can be produced to flow outside the dust collecting opening from the air outlet along the first turning direction. Therefore, the dust on the fin assembly at the air outlet can be sucked toward the dust collecting opening such that the dust on the fin assembly can be cleaned out effectively and the heat dissipation efficiency of the heat dissipation module can be restored.

What is claimed is:

1. A dust removal method of an electronic device, the electronic device comprising a first body, a heat dissipation module, a first cover plate and a second cover plate, the first body including a heat dissipation opening, the heat dissipation module being assembled in the first body, the heat dissipation module comprising a fan and a fin assembly, the fan comprising a fan case body and a blade assembly disposed inside the fan case body, wherein the fan case body includes an air inlet, an air outlet and a dust collecting opening, the air outlet and the heat dissipation opening are connected with each other, the first cover plate is installed in a position of the first body adjacent to the dust collecting opening or in a position of the fan case body adjacent to the dust collecting opening, the first cover plate is used for sealing off the dust collecting opening, the second cover plate is installed in the first body and is used for sealing off the air inlet, when the blade assembly turns toward a first turning direction, the first cover plate covers the dust collecting opening, a heat dissipating air current flows inside the heat dissipation module from the air inlet and flows out from the air outlet towards the fin assembly, the dust removal method of the electronic device comprises steps of:
inserting the second cover plate for sealing off the air inlet of the fan case body;
turning the first cover plate pivotally toward the blade assembly in order to expose the dust collecting opening; and
turning the blade assembly toward the first turning direction, and a dust collecting air current is suitable for flowing outside the dust collecting opening from the air outlet along the first turning direction.

2. An electronic device, for performing a heat dissipation operation or a dust collecting operation, the electronic device, comprising:
a first body including a heat dissipation opening;
a heat dissipation module assembled in the first body, the heat dissipation module comprising a fan, the fan including a fan case body and a blade assembly disposed inside the fan case body, wherein the fan case body including an air inlet, an air outlet and a dust collecting opening, and the air outlet and the heat dissipation opening are connected with each other;
a first cover plate installed in a position of the first body adjacent to the dust collecting opening or in a position of the fan case body adjacent to the dust collecting opening, and the first cover plate being used for sealing off the dust collecting opening, and
a second cover plate installed in the first body and being used for sealing off the air inlet, wherein during the heat dissipation operation, the blade assembly turns toward a first turning direction, the first cover plate covers the dust collecting opening, a heat dissipating air current flows inside the heat dissipation module from the air inlet and flows out from the air outlet, during the dust collecting operation, the blade assembly turns toward the first turning direction, the first cover plate opens the dust collecting opening, the second cover plate seals off the air inlet, and a dust collecting air current flows outside the dust collecting opening from the air outlet along the first turning direction.

3. The electronic device as claimed in claim 2, wherein an end of the first cover plate is pivotally connected along an axis to the position of the first body adjacent to the dust collecting opening or pivotally connected to the position of the fan case body adjacent to the dust collecting opening, in the dust collecting operation, the other end of the first cover plate turns around the axis in order to open the dust collecting opening.

4. The electronic device as claimed in claim 2, wherein the other end of the first cover plate turns toward the blade assembly.

5. The electronic device as claimed in claim 2, wherein the first body further includes an inserting opening for being inserted by the second cover plate.

6. The electronic device as claimed in claim 2, further comprising a second body and a pivotal turning mechanism pivotally connected between the first body and the second body, the first body having a first portion and a second portion disposed underneath the first portion, the first portion comprising a keyboard, the heat dissipation module being disposed in the second portion, wherein when an end of the second body turns toward a direction away from the first body, the pivotal turning mechanism drives at least a part of the first portion to detach from the second portion.

7. The electronic device as claimed in claim 2, wherein the heat dissipation module further comprises a fin assembly, and an end of the fin assembly is disposed at the air outlet.

8. A heat dissipation module, for assembling in a first body to be adapted to perform a heat dissipation operation or for installing with a second cover plate to be adapted to perform a dust collecting operation, the heat dissipation module comprising:
a fan comprising a fan case body and a blade assembly disposed inside the fan case body, wherein the fan case body includes an air inlet, an air outlet and a dust collecting and
a first cover plate installed in a position of the first body adjacent to the dust collecting opening or in a position of the fan case body adjacent to the dust collecting opening, and the first cover plate being used for sealing off the dust collecting opening;
wherein during the heat dissipation operation, the blade assembly turns toward a first turning direction, the first cover plate covers the dust collecting opening, and a heat dissipating air current flows inside the heat dissipation module from the air inlet and flows out from the air outlet, during the dust collecting operation, the blade assembly turns toward the first turning direction, the first cover plate opens the dust collecting opening, the second cover plate seals off the air inlet, and a dust collecting air current flows outside the dust collecting opening from the air outlet along the first turning direction.

9. The heat dissipation module as claimed in claim 8, wherein the air outlet is disposed adjacent to the dust collecting opening, and the first cover plate is pivotally connected to the fan case body between the air outlet and the dust collecting opening.

10. The heat dissipation module as claimed in claim 8, wherein the heat dissipation module further comprises a fin assembly, and an end of the fin assembly is disposed at the air outlet.
